(19) United States
(12) Patent Application Publication
(10) Pub. No.: US 2002/0173179 A1
(43) Pub. Date: Nov. 21, 2002

(54) IC socket and method of mounting IC package

(75) Inventors: Takehiro Ito, Tokyo (JP); Katsumi Suzuki, Tokyo (JP)

Correspondence Address: Finnegan, Henderson, Farabow,, Garrett & Dunner, L.L.P., 1300 I Street, N.W., Washington, DC, 20005-3315, US

(73) Assignee: YAMAICHI ELECTRONICS CO., LTD.

(21) Appl. No.: 10/143,966

(22) Filed: May 14, 2002

(30) Foreign Application Priority Data
May 16, 2001 (JP) 2001-146524
Sep. 10, 2001 (JP) 2001-274054

(51) Int. Cl. H05K 1/00

(52) U.S. Cl. 439/70

(57) ABSTRACT

In order to form a sufficient space between the free end portions of the cantilevered spring type of the contacts of the contact sheet for the IC socket and the wires of the test board, to obtain a sufficient elastic displacement of the free end portions of the contacts, and to improve the test efficiency, the IC socket of the present invention comprising the socket frame mounted to the test board through the contact sheet is characterized by comprising the contact sheet having a plurality of cantilevered spring contacts arrayed on the insulating film, and the method of mounting the IC package of the present invention is characterized by comprising a first step of mounting the contact sheet to the carrier concurrently used as a socket frame, and a second step of mounting the carrier to the test board, installing the IC package in the carrier and mounting the pusher.

This application is based on Japanese Patent Application Nos. 2001-146524 filed May 16, 2001 and 2001-274054 filed Sep. 10, 2001, the contents of which are incorporated herein by reference.

### BACKGROUND OF THE INVENTION

1. Field of the Invention

The present invention relates to an IC socket having a socket frame mounted to a test board through a contact sheet for a variety of tests on an IC package, and to a method of mounting an IC package for tests. More specifically, the present invention relates to a high frequency test socket mounted with an IC package on a socket frame through a contact sheet on a test board, and a method of directly mounting an IC package-attached carrier to the test board.

2. Description of the Related Art

For a variety of tests on IC packages as electric parts, IC sockets such as high frequency test sockets have been known, in which a socket frame is mounted to a test board through a contact sheet. An IC package to be tested is installed in such an IC socket and held by a pusher or retainer plate. Another type of IC socket is also known, in which a socket block attached with contact pins is mounted in a fixed socket body portion of the IC socket and is firmly held by the retainer plate.

One such conventional IC socket and a process of manufacturing it are shown in FIG. 14 to FIG. 21. FIG. 14 is an external perspective view of a conventional IC socket. FIG. 15 is an exploded perspective view of the conventional IC socket of FIG. 14. FIG. 16 is a perspective view of a contact sheet of the conventional IC socket of FIG. 15. FIG. 17 is a central vertical cross section of the conventional contact sheet of FIG. 16. FIG. 18 is a central vertical cross section showing contacts and a socket frame provided on the contact sheet in a first step of manufacturing the contacts in the process of manufacturing the conventional IC socket of FIG. 14. FIG. 19 is a central vertical cross section showing the contacts and the socket frame mounted on the contact sheet in a second step of manufacturing the contacts of the conventional IC socket following the first step of FIG. 18. FIG. 20 is a central vertical cross section showing an IC package disposed on the contacts of the conventional IC socket manufactured as shown in FIG. 19. FIG. 21 is a central vertical cross section showing the IC package pushed down in the conventional IC socket from the state of FIG. 20.

As shown in FIG. 14 to FIG. 21, a conventional IC socket 100 comprises a contact sheet 102 put on a test board 101 and a socket frame 103 placed on the contact sheet 102, the contact sheet 102 and the socket frame 103 are fastened together by screws 104 and nuts 105.

The contact sheet 102 has an array of elastic metal strip contacts 107 attached to an insulating film 108 of, for example, polyimide. The elastic metal strip contacts 107 have one of their two ends located on wires 106 on the test board 101, with the insulating film 108 bonded to them from above. The contacts 107 have their free end portion curved in wave.

A process of testing for each IC package 110 by using this IC socket 100 involves, as shown in FIG. 15 to FIG. 21, putting the contact sheet 102 on the test board 101, arranging the socket frame 103 on the contact sheet 102, fastening them with screws 104 and nuts 105, installing the IC package 110 in the socket frame 103 so that IC leads 111 are provided on the contacts 107, and then pushing the IC package 110 with a pusher (not shown). In this construction, the free ends of the contacts 107 come into direct contact with the wires 106 of the test board 101 so that the contacts are supported at both ends. This configuration produces almost no elastic displacement of the contacts 107, making it impossible to adjust the contact force or the amount of displacement of the contacts. This in turn degrades the durability of the contacts and their reduced elasticity results in a failure to produce a sufficient elastic displacement. Further, such a conventional IC socket 100 takes time to complete a test and the test itself is no easy task. Moreover, the number of parts in the IC socket 100 is large, which in turn increases the cost.

Further, the conventional IC package described above is inserted into the IC socket on the test board by an automated machine or manually. Hence, in a test of the IC package, a contact sheet 202 is placed on a test board 201; a socket frame 203 is arranged on the contact sheet 202; and they are fastened together with screws 204 and nuts 208, as shown in FIG. 22. On this securely fixed socket frame 203 is mounted a carrier 205, in which an IC package 206 is then installed and pushed by a pusher 207. Thus, the test procedure takes time and is not an easy task. Moreover, the number of parts such as the socket frame 203 and so on is large, raising the production cost.

A first object of the present invention is therefore to provide an IC socket in which, to solve one of the conventional problems described above, the contacts of the contact sheet are formed as cantilevered springs to form a sufficient gap between the free end portions of the contacts and the test board and thereby produce a sufficient elastic displacement of the free end portions of the contacts.

A second object of the present invention is to provide a method of mounting an IC package to mount an IC package-attached carrier onto the test board, in which, to solve another of the conventional problems described above, the socket frame is eliminated to reduce the number of parts and the IC package-attached carrier is directly mounted on the test board to improve a test efficiency.

### SUMMARY OF THE INVENTION

To achieve the first objective, the present invention provides an IC socket comprising a socket frame mounted to a test board through a contact sheet, wherein the contact sheet has a plurality of cantilevered spring contacts arrayed on an insulating film, so that the IC leads of the IC package are elastically supported on the cantilevered spring contacts of the contact sheet, and thus the maximum stress of the contacts can be lowered, thereby making it possible to easily adjust the contact force and the amount of displacement and contributing to an improvement of the durability of the contacts.

Further, since the cantilevered spring contacts are made from elastic metal strips and arrayed to oppose each other, the contacts can be manufactured properly to produce an IC socket that can elastically support the IC package in good condition.

Still further, since the cantilevered spring contacts each have one end portion fixed and the other end portion as a free end portion curved so that the free end portion is disposed above the test board with a space therebetween, the IC leads of the IC package are elastically and displaceably supported on the cantilevered spring contacts of the contact sheet, making it possible to lower the maximum stress of the contacts, and furthermore it allows the contact force and the amount of displacement to be adjusted easily and also contributes to an improvement of the durability of the contacts.

Still further, since the insulating film of the contact sheet mounted to the socket frame is polyimide, the IC socket can be made easily and inexpensively.

Yet further, since an IC package of a flat plate type is mounted in the socket frame which is mounted to the test board through the contact sheet, the IC package can be installed appropriately and it is possible to adjust the contact force and the amount of displacement of the contacts and to improve the durability of the contacts.

Since the IC leads of the IC package of the flat plate type are brought into contact with the cantilevered spring contacts of the contact sheet, it is possible to eliminate a carrier itself and thereby reduce the number of parts and to mount directly a socket frame cooperated as a carrier to the test board and thereby improve the test efficiency.

Further, to achieve the second objective, the present invention provides a method of mounting an IC package comprising: a first step of mounting a contact sheet to a carrier concurrently used as a socket frame; and a second step of mounting the carrier to a test board, installing an IC package in the carrier and mounting a pusher, so that it is therefore possible to omit the socket frame to reduce the number of parts and to directly mount the IC package-attached carrier to the test board to improve the test efficiency.

Still further, since the IC package is of a ball grid array type, it can be mounted properly.

Yet further, since the IC package is of a quad flat plate type, it can be mounted properly.

Since the first step of mounting the contact sheet to the carrier can be performed separately in advance, the second step can be performed separately from the first step.

Furthermore, since the IC package of the ball grid array type or quad flat plate type is mounted in the second step to the carrier which was mounted in the first step to the test board, the first and second steps can be performed separately and properly.

The above and other objects, effects, features and advantages of the present invention will become more apparent from the following description of embodiments thereof taken in conjunction with the accompanying drawings.

### BRIEF DESCRIPTION OF THE DRAWINGS

FIG. 1 is an external perspective view of an IC socket according to Embodiment 1 of the present invention;

FIG. 2 is an exploded perspective view of the IC socket of FIG. 1 according to Embodiment 1 of the present invention;

FIG. 3 is a perspective view of a contact sheet of the IC socket of FIG. 2 according to Embodiment 1 of the present invention;

FIG. 4 is a central vertical cross-sectional view of the contact sheet of FIG. 3;

FIG. 5 is an outline perspective view of one contact of the IC socket of FIG. 1 according to Embodiment 1 of the present invention;

FIG. 6 is a central vertical cross-sectional view showing contacts and a socket frame, both arranged over the contact sheet, in a first step of assembling the contacts in a process of manufacturing and assembling the IC socket of FIG. 1 according to Embodiment 1 of the invention;

FIG. 7 is a central vertical cross-sectional view showing the contacts and the socket frame, both mounted on the contact sheet, in the next step of assembling the contacts of the IC socket of the invention following the first step of FIG. 6;

FIG. 8 is a central vertical cross-sectional view showing an IC package arranged on the contacts of the IC socket of the invention manufactured and assembled as shown in FIG. 7;

FIG. 9 is a central vertical cross-sectional view showing the IC package arranged as shown in FIG. 8 and pushed down in the IC socket of the invention;

FIG. 10 is a schematic view showing a first step in the method of mounting an IC package according to a second embodiment of the invention;

FIG. 11 is a schematic view showing a second step following FIG. 10 in the method of mounting the IC package according to the second embodiment of the invention;

FIG. 12 is a schematic view showing a first step in the method of mounting an IC package according to a third embodiment of the invention;

FIG. 13 is a schematic view showing a second step following FIG. 12 in the method of mounting the IC package according to the third embodiment of the invention;

FIG. 14 is an external perspective view of a conventional IC socket;

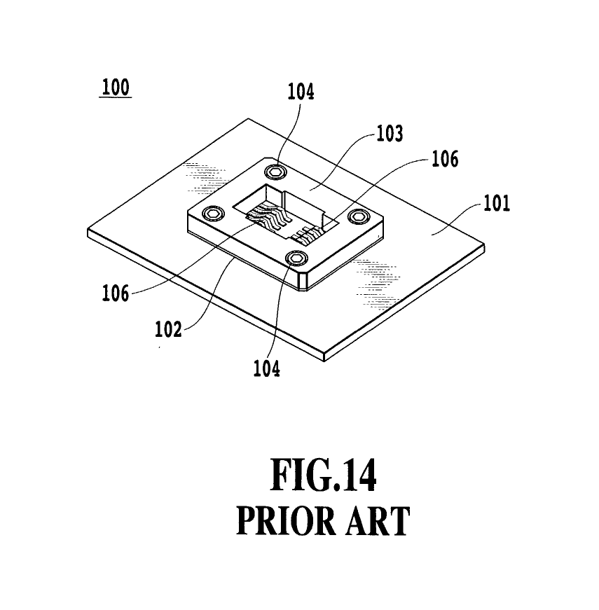

FIG. 15 is an exploded perspective view of the conventional IC socket of FIG. 14;

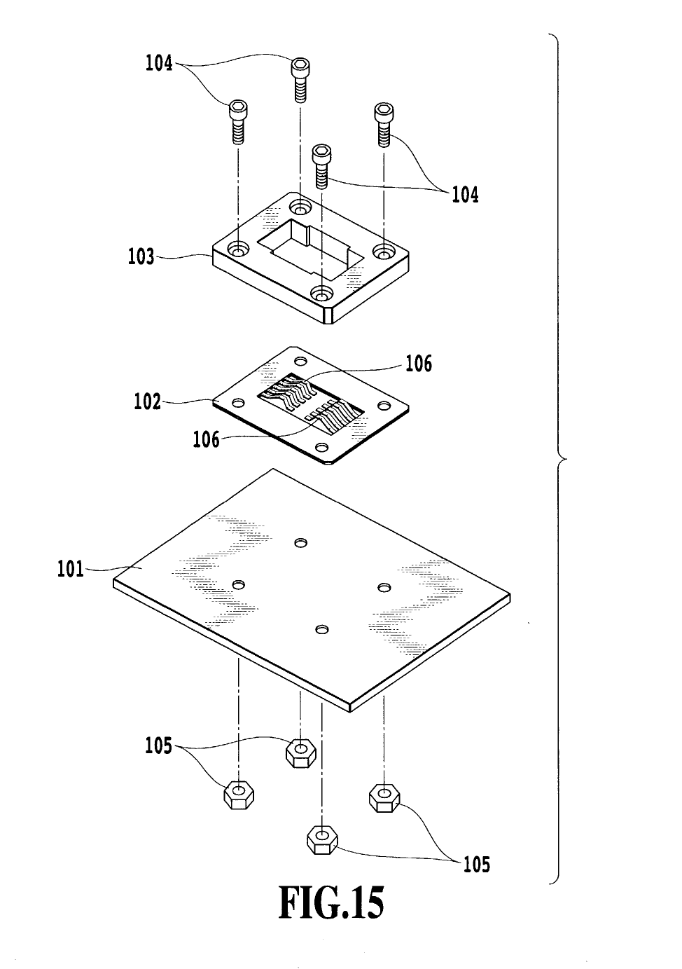

FIG. 16 is a perspective view of a contact sheet of the conventional IC socket of FIG. 15;

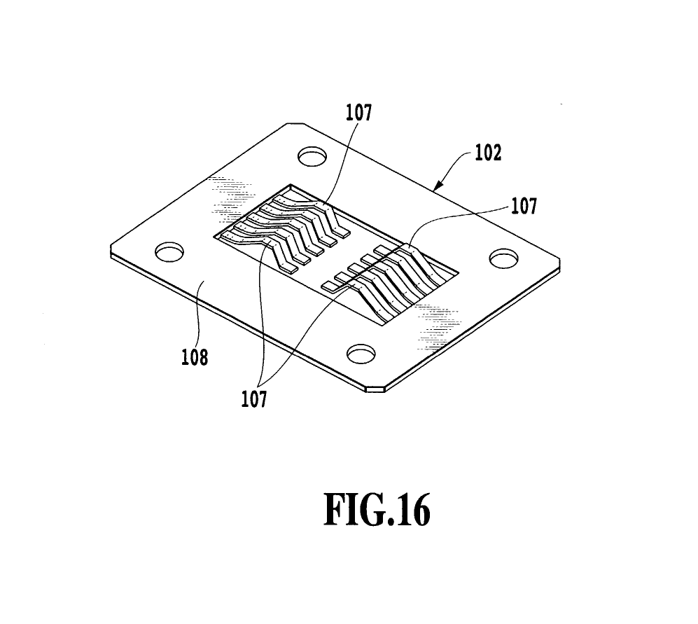

FIG. 17 is a central vertical cross-sectional view of the conventional contact sheet of FIG. 16;

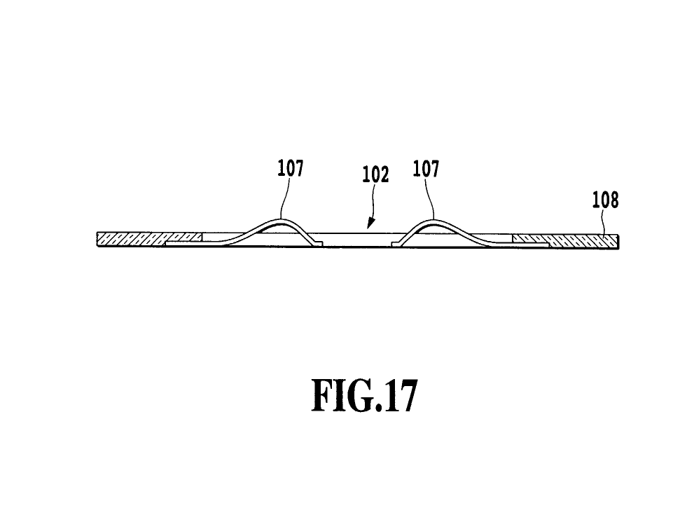

FIG. 18 is a central vertical cross-sectional view showing contacts and a socket frame, both arranged over the contact sheet, in a first step of assembling the contacts in a process of manufacturing the conventional IC socket of FIG. 14;

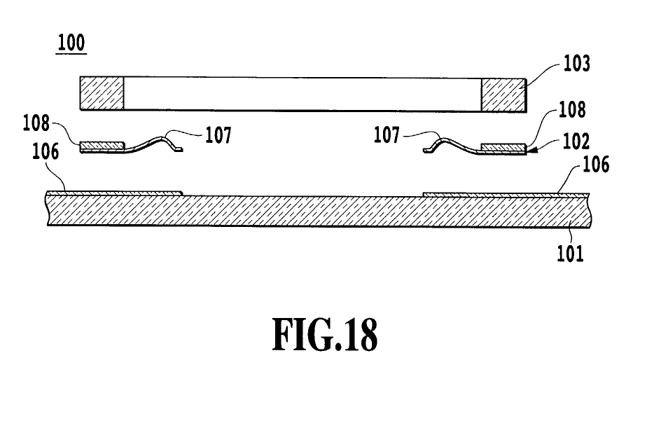

FIG. 19 is a central vertical cross-sectional view showing the contacts and the socket frame, both mounted on the contact sheet, in a second step of manufacturing the contacts of the conventional IC socket following the first step of FIG. 18;

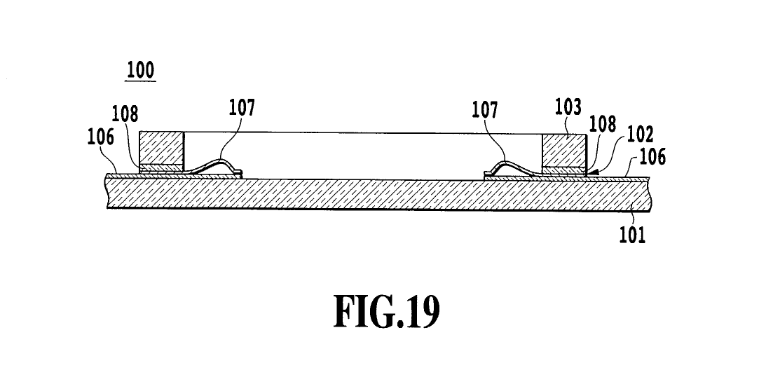

FIG. 20 is a central vertical cross-sectional view showing an IC package arranged on the contacts in a third step of manufacturing the contacts of the conventional IC socket following the second step of FIG. 19;

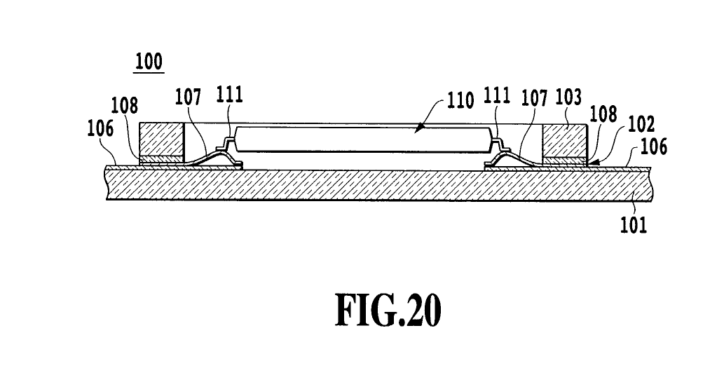

FIG. 21 is a central vertical cross-sectional view showing the IC package arranged and pushed down onto the contacts in a fourth step of manufacturing the contacts of the conventional IC socket following the third step of FIG. 20; and

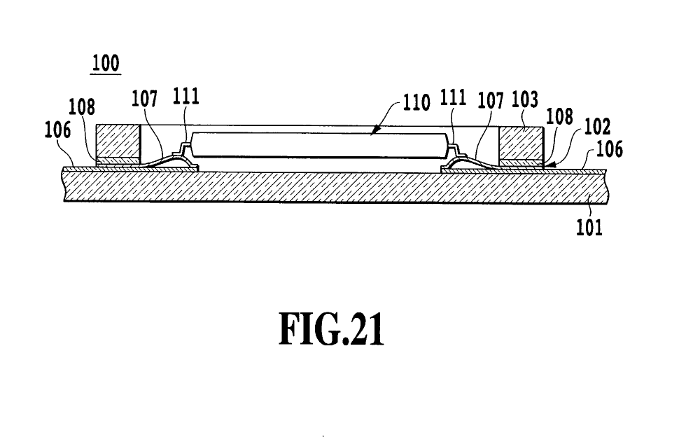

FIG. 22 is a schematic view showing a conventional method of mounting an IC package.

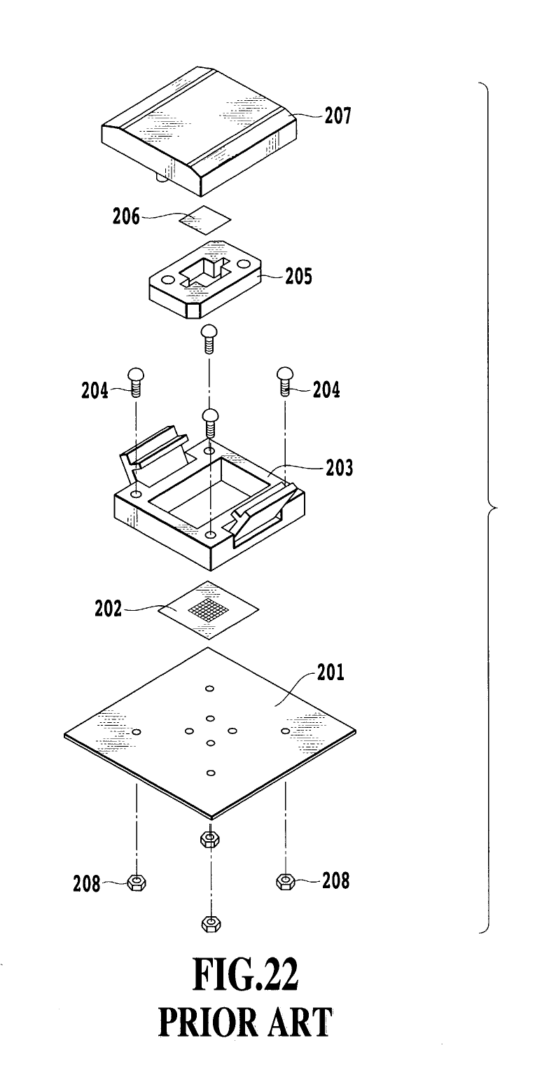

### DETAILED DESCRIPTION OF PREFERRED EMBODIMENTS

### EMBODIMENT 1

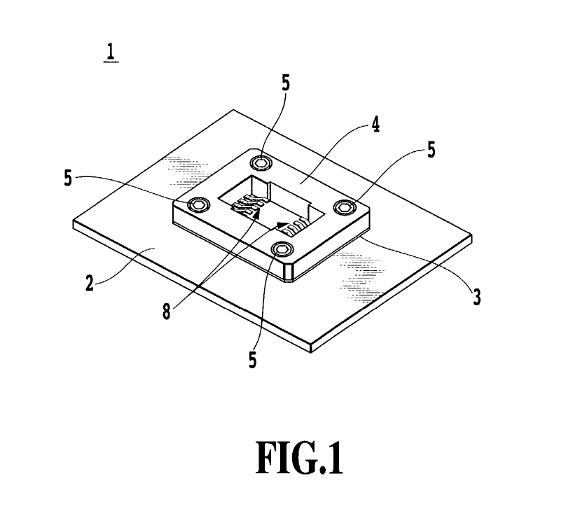

An IC socket and a process of manufacturing it according to the present invention are shown in FIGS. 1 through 9.

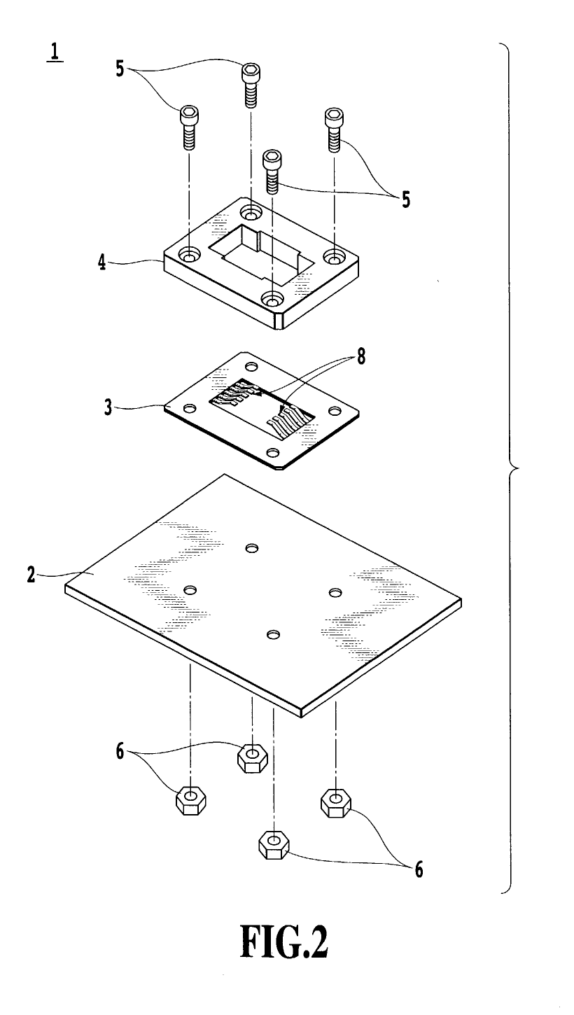

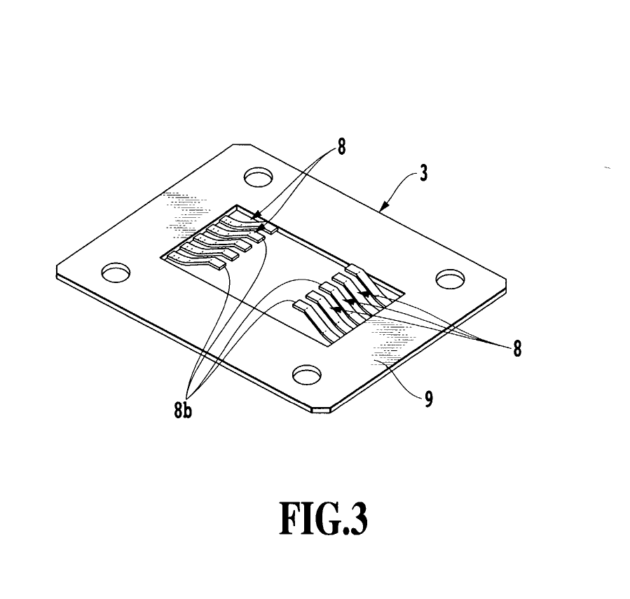

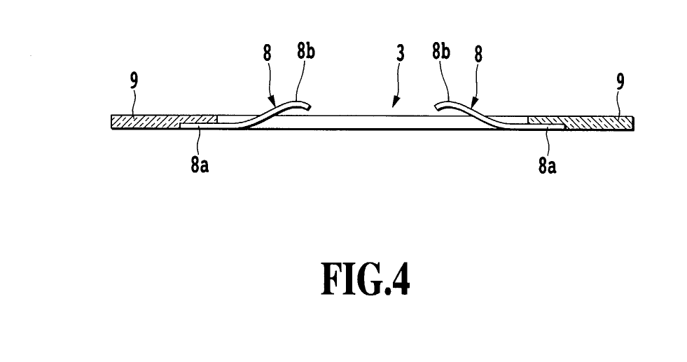

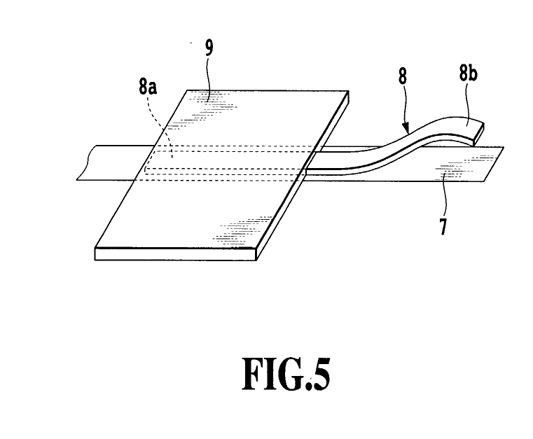

FIG. 1 is an external perspective view of an IC socket of the present invention. FIG. 2 is an exploded perspective view of the IC socket of FIG. 1 of the invention. FIG. 3 is a perspective view of a contact sheet of the IC socket of the invention. FIG. 4 is a central vertical cross section of the contact sheet of FIG. 3 of this invention. FIG. 5 is an enlarged perspective view of one of the contacts of the contact sheet of FIG. 4.

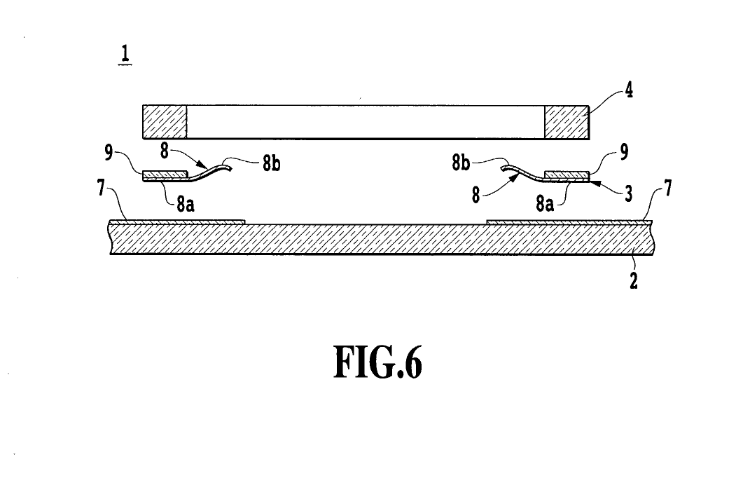

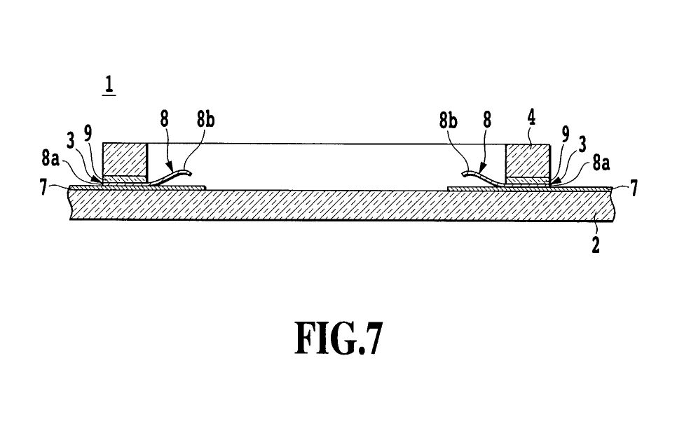

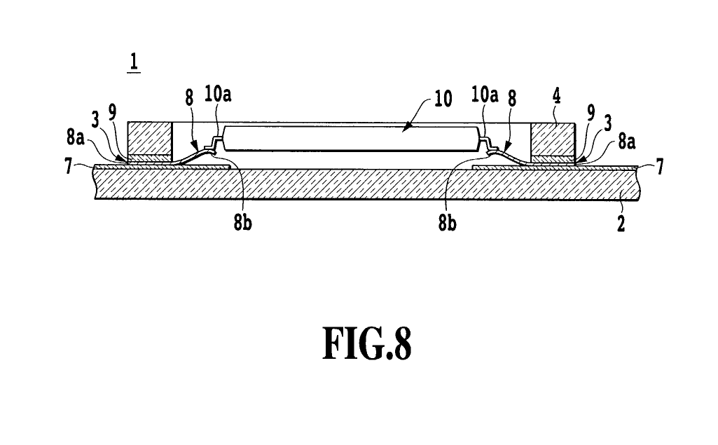

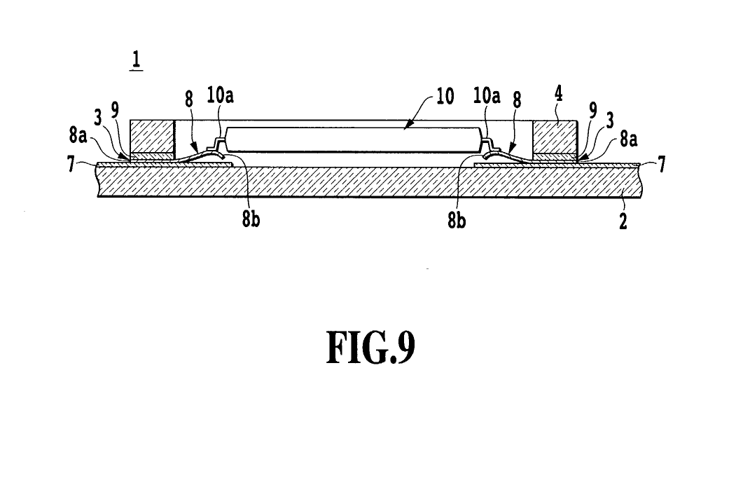

Further, FIG. 6 is a central vertical cross section showing contacts and a socket frame, both arranged over the contact sheet, in a first step of assembling the contacts in the process of manufacturing and assembling the IC socket according to the present invention. FIG. 7 is a central vertical cross section showing the contacts and the socket frame, both mounted on the contact sheet, in the next step of manufacturing the contacts of the IC socket of the invention following the first step of FIG. 6. FIG. 8 is a central vertical cross section showing an IC package arranged on the contacts of the IC socket of the invention manufactured and assembled as shown in FIG. 7. FIG. 9 is a central vertical cross section showing an IC package arranged as shown in FIG. 8 and pushed down in the IC socket of the invention.

FIG. 1 and FIG. 2 are schematic views showing an IC socket of the invention for receiving a flat plate type IC package, FIG. 1 representing an external perspective view of the IC socket and FIG. 2 representing an exploded perspective view of the IC socket of FIG. 1.

As shown in FIG. 1 and FIG. 2, the IC socket 1 as one embodiment of the present invention comprises a contact sheet 3 placed on a test board 2 and a socket frame 4 concurrently used as a carrier mounted on the contact sheet 3, with the test board 2, the contact sheet 3 and the socket frame 4 fastened together with screws 5 and nuts 6.

In such an IC socket 1 of the present invention, the contact sheet 3 as shown in FIG. 3 to FIG. 5 has a plurality of cantilevered elastic metal strip contacts 8 arranged to oppose each other and attached to an insulating film 9 of, for example, polyimide. The cantilevered contacts 8 have one end portion 8a, which is an outer end portion of each elastic metal strip, arranged as a fixed end portion and positioned on a wire 7 of the test board 2. The insulating film 9 is securely bonded to the fixed end portions of the contacts 8 from above. The other end portion 8b of each contact 8, such as an inner free end portion of each elastic metal strip, is disposed over the wire 7 with a gap therebetween and is shaped in wave, e.g., curved upwardly convex.

The cantilevered contacts 8 of the present invention as described above have the inner free end portion 8b extend upwardly in wave, i.e., curved upwardly convex as shown. Each of the contacts 8 is cantilevered so that the free end portion 8b is disposed with a sufficient distance above the insulating film 9 to allow its sufficient elastic displacement.

Hence, in the test of an IC package 10, the contact sheet 3 is placed on the test board 2, the socket frame 4 as a carrier is mounted on the contact sheet 3, with all these components fastened together with screws 5 and nuts 6, as shown in FIG. 1 and FIG. 2. Then, an IC package 10 is installed in the fixed socket frame 4, as shown in FIG. 8 and FIG. 9, with IC leads 10a arranged on the contacts 8 and pressed against them by a pusher (not shown).

As described above, the free end portions 8b of the contacts 8 of the present invention are disposed over the wires 7 of the test board 2 with a sufficient space therebetween so that the contacts 8 are properly constructed as cantilevered spring contacts and can be elastically displaced by a sufficient amount. This in turn makes it possible to appropriately adjust the contact force and the amount of displacement and also improve the durability of the contacts. Further, the IC socket 1 of the present invention allows a test to be performed easily and quickly in a simple procedure and also contributes to a reduction in the number of parts and therefore cost.

With the present invention, the contacts 8 in the contact sheet 3 of the IC socket 1 are formed as cantilevered spring contacts, as shown in FIG. 3 to FIG. 5. The process of assembling the IC socket 1 of the present invention having such contacts 8 will be described with reference to FIG. 6 to FIG. 9.

The following explanation concerns an IC socket 1 of the present invention for a flat plate type IC package 10.

As shown in FIG. 6, a first step involves putting the contact sheet 3 on the test board 2, arranging the socket frame 4 as a carrier on the contact sheet 3, and fastening them to the test board 2 with screws 5 and nuts 6.

As a second step, in the socket frame 4 which is fixed to the test board 2 through the contact sheet 3 as shown in FIG. 7, an IC package 10 is installed so that the IC leads 10a are positioned on the contacts 8, as shown in FIG. 8. In this case, the contacts 8 have their free end portions 8b spaced with a sufficient distance from the wires 7 on the test board 2, as shown, so that the contacts 8 as cantilevered spring contacts can support the IC leads 10a of the IC package 10 with a sufficient elasticity.

Next, the IC package 10 mounted as shown in FIG. 8 is pressed down by an appropriate pusher (not shown) to bring the IC leads 10a of the IC package 10 into contact with the contacts 8 with a sufficient force, thus establishing a good electrical connection between the IC package 10 and the wires 7 of the test board 2.

In the IC socket 1 of the present invention, as described above, since in the first step the socket frame 4 as a carrier is mounted on the test board 2 through the contact sheet 3 and, in the second step, the IC package 10 is installed in the socket frame 4, the cantilevered spring contacts 8 of the contact sheet 3 elastically support the IC leads 10a of the IC package 10 and thereby lower the maximum stress of the contacts 8, which in turn allows the contact force and the amount of displacement to be adjusted easily, improving the durability of the contacts.

### EMBODIMENT 2

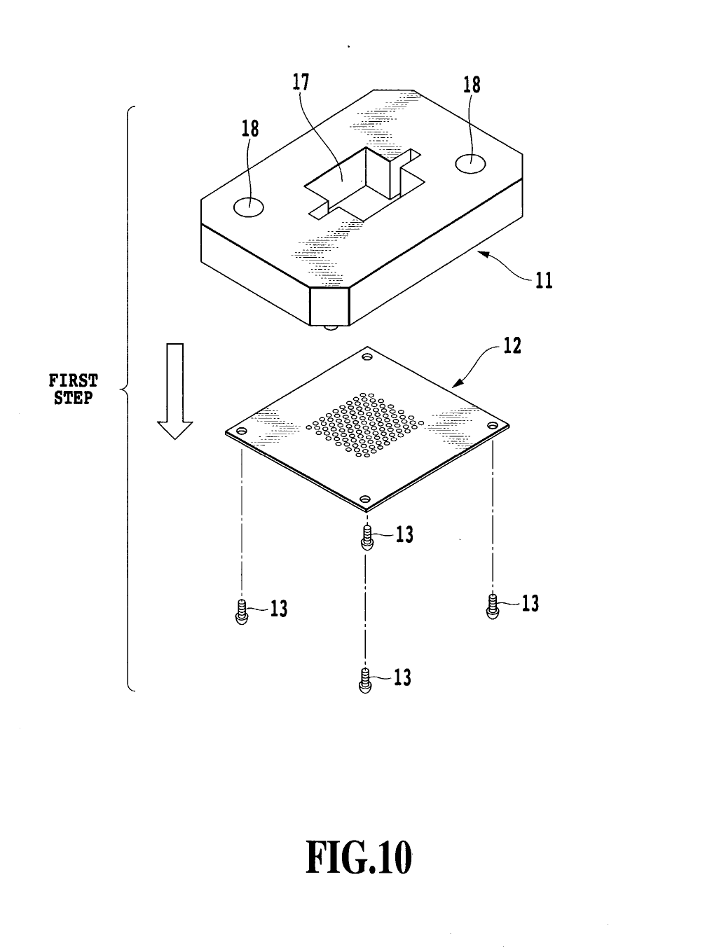

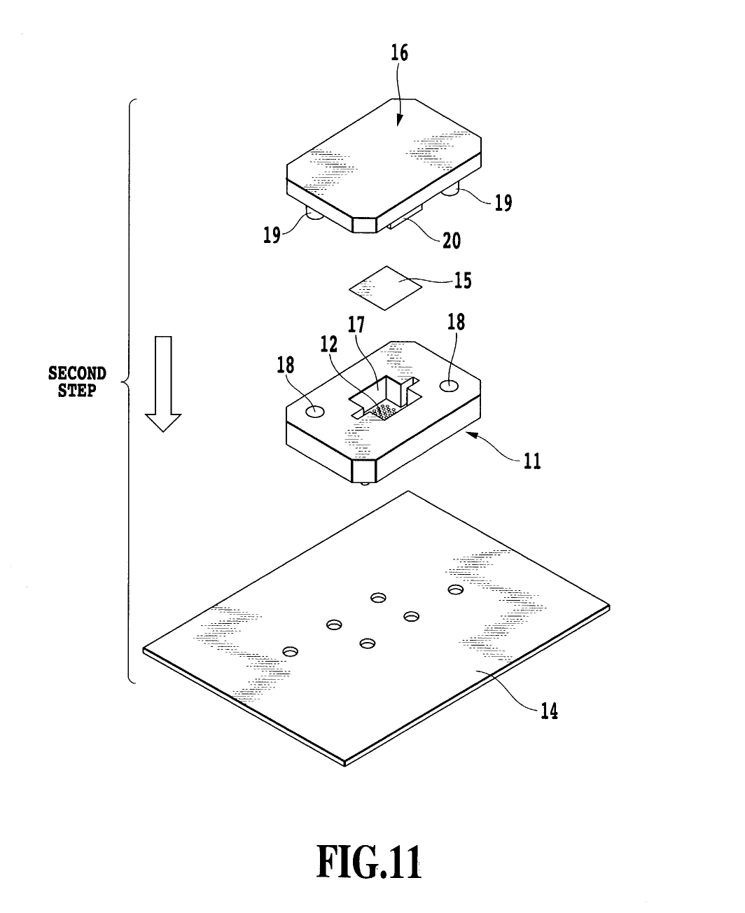

FIG. 10 and FIG. 11 are schematic diagrams showing a process of mounting an IC package when the IC package of the present invention is of a ball grid array type, with FIG. 10 representing a first step and FIG. 11 representing a second step.

As shown in FIG. 10 and FIG. 11, the IC package mounting method according to the second embodiment of the present invention concerns a ball grid array type of IC package.

As shown in FIG. 10, in the first step of the present invention, a contact sheet 12 for a ball grid array type of IC package 15 is fastened to a carrier 11 concurrently used as a socket frame with a plurality of screws 13. The carrier 11 has a hole 17 at almost the center in which to mount the IC package 15 and also two holes 18 located diagonally of the carrier with the hole 17 therebetween, in which mounting legs 19 of a pusher 16 are to be inserted. The pusher 16 has a raised press portion 20 at almost the center of underside thereof which is to be fitted into the hole 17 of the carrier 11 to push down the IC package 15.

The second step of the present invention involves, as shown in FIG. 11, mounting the carrier 11 attached with the contact sheet 12 in the first step to a test board 14, installing the IC package 15 in the center hole 17 of the carrier 11 and mounting the pusher 16.

In the second step, the pusher 16 is mounted to the carrier 11 by fitting its raised press portion 20 in the center hole 17 in the carrier 11 and its paired mounting legs 19 in the corresponding holes 18 in the carrier 11.

In the IC package mounting method of this embodiment, as described above, since in the first step the contact sheet 12 is attached to the carrier 11 concurrently used as a socket frame in advance and, in the second step, the carrier 11 attached with the contact sheet 12 is mounted to the test board 14 and the IC package 15 is fitted in the carrier 11, it is possible to omit the socket frame that is used in the conventional IC socket. Because the number of parts is one less than that in the conventional IC socket and the number of steps for the IC package mounting is also reduced by one; thus reducing the time and labor required, improving the IC package mounting work efficiency and lowering the running cost of, for example, burn-in tests.

### EMBODIMENT 3

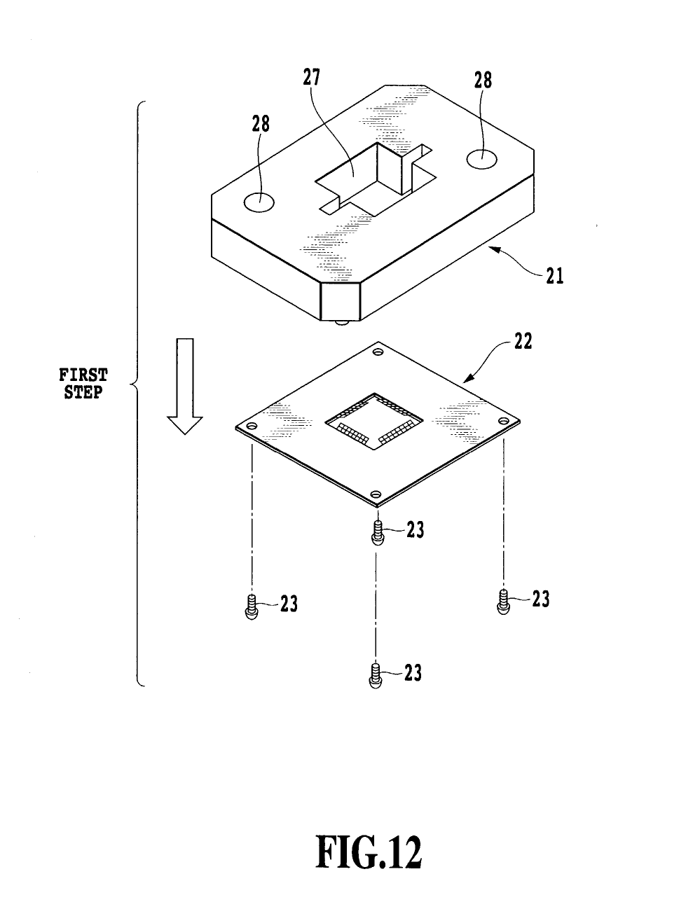

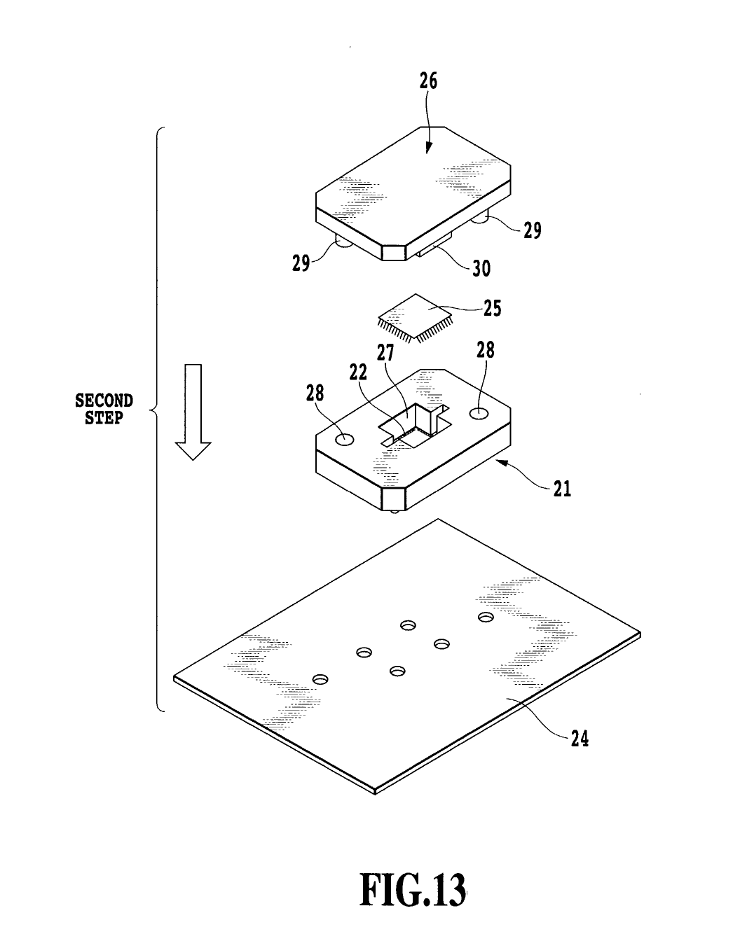

FIG. 12 and FIG. 13 are schematic diagrams showing another IC package mounting method of the present invention when the IC package is of a quad flat plate type, with FIG. 12 representing a first step and FIG. 13 representing a second step. The IC package mounting method of this embodiment differs from that of Embodiment 2 in that the IC package is of a quad flat plate type. Thus, a contact sheet used, too, is of a quad flat plate type.

In the first step of the present invention, as shown in FIG. 12, a contact sheet 22 for an IC package 25 of a quad flat plate type is fastened to a carrier 21 concurrently used as a socket frame with a plurality of screws 23. The carrier 21 has a hole 27 at almost the center for mounting the IC package 25 and also two holes 28 located diagonally of the carrier with the hole 27 therebetween, in which mounting legs 29 of a pusher 26 are to be inserted. The pusher 26 has a raised press portion 30 at almost the center of the underside surface thereof which is to be fitted into the hole 27 of the carrier 21 to push down the IC package 25.

The second step of the present invention involves, as shown in FIG.13, mounting the carrier 21 attached with the contact sheet 22 in the first step to a test board 24, installing the quad flat plate type IC package 25 in the center hole 27 of the carrier 21 and mounting the pusher 26.

In the second step, the pusher 26 is mounted to the carrier 21 by fitting its raised press portion 30 in the center hole 27 of the carrier 21 and its paired mounting legs 29 in the corresponding holes 28 of the carrier 21.

In the IC package mounting method of this embodiment, as described above, since in the first step the contact sheet 22 is attached to the carrier 21 in advance and, in the second step, the carrier 21 attached with the contact sheet 22 is mounted to the test board 24 and the IC package 25 is fitted in the carrier 21, it is possible, as in Embodiment 1, to omit the socket frame that is used in the conventional IC socket. Because the number of parts is one less than that in the conventional IC socket, the number of steps for the IC package mounting is also reduced by one, thus reducing the time and labor required, improving the IC package mounting work efficiency and lowering the running cost of, for example, burn-in tests.

The present invention has been described in detailed with respect to the preferred embodiments, and will now be apparent from the. foregoing to those skilled in the art that changes and modifications may be made without departing from the invention in its broader aspect, and it is the intention, therefore, in the appended claims to cover all such changes and modifications as fall within the true sprit of the invention.

What is claimed is:

1. An IC socket comprising a socket frame mounted to a test board through a contact sheet, characterized by comprising:
the contact sheet has a plurality of cantilevered spring contacts arrayed on an insulating film.

2. An IC socket according to claim 1, wherein the cantilevered spring contacts are made from elastic metal strips and arrayed to oppose each other.

3. An IC socket according to claim 1, wherein the cantilevered spring contacts each have one end portion fixed and the other end portion as a free end portion curved so that the free end portion is disposed above the test board with a space therefrom.

4. An IC socket according to claim 1, wherein the insulating film of the contact sheet mounted to the socket frame is polyimide.

5. An IC socket according to claim 1, wherein an IC package of a flat plate type is mounted in the socket frame which is mounted to the test board through the contact sheet.

6. An IC socket according to claim 5, wherein IC leads of the IC package of the flat plate type are brought into contact with the cantilevered spring contacts of the contact sheet.

7. A method of mounting an IC package, characterized by comprising:
a first step of mounting a contact sheet to a carrier concurrently used as a socket frame; and
a second step of mounting the carrier to a test board, installing an IC package in the carrier and mounting a pusher.

8. A method of mounting an IC package according to claim 7, wherein the IC package is of a ball grid array type.

9. A method of mounting an IC package according to claim 7, wherein the IC package is of a quad flat plate type.

10. A method of mounting an IC package according to claim 7, wherein the first step of mounting the contact sheet to the carrier can be performed separately in advance.

11. A method of mounting an IC package according to claim 7, wherein the IC package of the ball grid array type or quad flat plate type is mounted in the second step to the carrier which was mounted in the first step to the test board.
